(19) United States
(12) Patent Application Publication
(10) Pub. No.: US 2025/0393172 A1
(43) Pub. Date: Dec. 25, 2025

(54) High Density Liquid Cooling Unit

(71) Applicant: Vertiv Corporation, Westerville, OH (US)

(72) Inventors: Oliver McKenzey Miller, Westerville, OH (US); Colin Lewis Blaser, Westerville, OH (US); Thomas Christopher Breuer, New Albany, OH (US); Matthew Alan Raven, Mount Gilead, OH (US)

(73) Assignee: Vertiv Corporation, Westerville, OH (US)

(21) Appl. No.: 19/247,928

(22) Filed: Jun. 24, 2025

Related U.S. Application Data
(60) Provisional application No. 63/664,133, filed on Jun. 25, 2024.

(51) Int. Cl. H05K 7/20

(52) U.S. Cl. CPC H05K 7/20772; H05K 7/20136; H05K 7/20263; H05K 7/20272; H05K 7/20281; H05K 7/20745

(57) ABSTRACT

A cooling system for cooling heat-generating components within a building. The cooling system comprises a cooling tower, a first fluid loop, a direct expansion (DX) loop, and a second loop. The first fluid loop communicates with the cooling tower and circulates a cooling tower fluid via a first pump. The DX loop communicates with the cooling tower. The DX loop circulates a refrigerant fluid and comprises an expansion valve and a compressor. The second fluid loop indirectly communicates with the DX loop, the first fluid loop, and the heat-generating components, and circulates a technical fluid via a second pump. The DX loop communicates with the cooling tower via a first brazed plate heat exchanger (BPHE) and communicates with the second fluid loop via a second BPHE. The first fluid loop communicates with the second fluid loop via a third BPHE. The heat-generating components are one or more servers.

### TECHNICAL FIELD

The present disclosure relates to a liquid cooling system, more specifically, to a high-density liquid cooling system for a data center.

### BACKGROUND

Data centers have ever-rising heat density, requiring thermal systems to provide increased cooling density. Additionally, recent trends toward higher-density data centers for artificial intelligence require higher heat rejection per footprint. Various cooling systems have been used to cool data centers, particularly, electronic devices (e.g., processors, memories, networking devices, chips, and other heat-generating devices) located on a server or network rack tray. For instance, forced convection may be created by providing a cooling airflow over the devices. Fans located near the devices, fans located in computer server rooms, and/or fans located in ductwork in fluid communication with the air surrounding the electronic devices, may force the cooling airflow over the tray containing the devices. A newer cooling method includes direct-to-chip liquid cooling, which can provide fluid to cool the electronics without using cooling fans. For instance, liquid may be sent to cold plates, mounted directly on heated electronic devices, to absorb the heat. This liquid is then transported to a coolant distribution unit (CDU) where a heat exchanger is used to dissipate the heat.

FIG. 1 shows a schematic view of a typical air cooling system 100 used in a data center 102 for cooling electronic devices. The system 100 includes typical HVAC components, e.g., an evaporator coil 104, a compressor 106, a condenser coil 108, and an expansion valve 110. In this air cooling system, air is blown across the evaporator coil 104 by a fan 112, and heat is transferred into a refrigerant causing the refrigerant to evaporate into a gas. Colder air is then able to return to the data center 102. The compressor 106 can pressurize the gas refrigerant to raise the temperature of the refrigerant higher than the ambient temperature air outside. Ambient temperature air is blown across the condenser coil 108 by a fan 114, and heat is then transferred from the vapor refrigerant to the air. This circulation condenses the refrigerant into a liquid. The colder refrigerant then returns to the evaporator coil 104 to recollect heat. Further, the expansion valve 110 helps control the refrigerant flowing through the evaporator coil 104 and to the compressor 106. This cycle helps control the quality of the refrigerant (% of liquid/gas) and ensures that the refrigerant is in the gas form before returning to the compressor 104 (liquids are incompressible and may damage the compressor).

As packaging densities increase, traditional air-cooling solutions are becoming prohibitively costly and inadequately effective. In addition, air cooling has other associated costs in the form of unwanted acoustic noise and energy consumption. Moreover, this approach increases the dust accumulation within the enclosure which leads to problems such as static electricity and surface degradation. In large “data centers” housing large numbers of computing and electronic systems in close proximity, the heat dissipation issue may be a serious issue. In such cases, cooling costs and the practical feasibility of providing air cooling have become especially burdensome.

FIG. 2 shows a schematic view of a typical direct-to-chip liquid cooling system 200. The direct-to-chip liquid cooling system 200 has some similarities to the air cooling system 100 described above. However, there is no need to blow air on an evaporator side to achieve heat transfer in the direct-to-chip liquid cooling system. Two components—a brazed plate heat exchanger (BPHE) 204 and a pump 212—are of especial significance in the layout of the system. Similar to the evaporator coil 104 of the air cooling system 100, heat is transferred from a secondary fluid (typically water or propylene glycol) to the refrigerant. However, in the BPHE 204, there is no need to blow air across to transfer the heat. The heat is transferred through conduction and convection as they pass through plates of the BPHE 204. The pump 212 can move the secondary fluid around a data center 202. The fluid can be also pumped directly to a server chip or to a cooling distribution unit (CDU) or servers 216 as used in larger data centers transitioning to liquid cooling. Another difference between the air cooling system and the direct-to-chip liquid cooling system is that there is a secondary fluid line 220 and 232, which is separated from a main fluid line 224 and 226 carrying a refrigerant between a condenser 208, the compressors 206, and the BPHE 204, for direct cooling of the servers 216. The fluid flowing in the secondary fluid line 220 and 232 is pumped by the pump 212 to the CDU or servers 216 and then is heated as passing therethrough. Then, the heat from the heated fluid is cooled at the BPHE 204 by the refrigerant passing through the main fluid line.

Industry trends and improvements in data chip technology are leading customers to adopt direct-to-chip liquid cooling solutions for several benefits. For instance, direct-to-chip cooling systems can pinpoint the specific components that generate heat. As a result, they can dissipate more heat with less energy, which is a win from a sustainability perspective (because lower energy consumption reduces data center carbon output) as well as from a reliability perspective. The better systems are at dissipating heat, the lower the risk of information technology (IT) failures due to overheating. However, as high-density data centers become more common, the need for efficient condensation into a smaller footprint, in addition to providing more cooling to the data center, is becoming increasingly important.

In view of the foregoing, there is a need for improved direct-to-chip cooling systems that can provide higher and more efficient cooling capabilities using existing infrastructure without increasing space usage (e.g., data center footprint).

### SUMMARY

Embodiments described herein relate to techniques for cooling data centers. In particular, systems and methods of the present disclosure provide new and novel direct-to-chip liquid cooling systems by utilizing a cooling tower in an inexpensive way, resulting in a solution that is not overly complex or expensive and adheres to existing standards.

In accordance with at least one embodiment of the present disclosure, a cooling system for cooling one or more heat-generating components within a building. The cooling system comprises at least one cooling tower disposed outside the building, a first fluid loop, a direct expansion (DX) loop, and a second loop. The first fluid loop directly communicates with the cooling tower. The first fluid loop is configured to circulate a cooling tower fluid and includes a first pump. The direct expansion (DX) loop indirectly communicates with the cooling tower. The DX loop is configured to circulate a refrigerant fluid and comprises an expansion valve and a compressor. The second fluid loop indirectly communicates with the DX loop, the first fluid loop, and one or more of the heat-generating components. The second fluid loop is configured to circulate a technical fluid and comprises a second pump. Furthermore, the DX loop communicates with the cooling tower via a first brazed plate heat exchanger (BPHE) and communicates with the second fluid loop via a second BPHE. Additionally, the first fluid loop communicates with the second fluid loop via a third BPHE. The DX loop and the second fluid loop are disposed of inside the building. The one or more heat-generating components are one or more servers.

In some embodiments, the second pump is configured to control a flow of the technical fluid in the second fluid loop. Additionally, the technical fluid in the second fluid loop has a lower temperature between the second pump and the one or more servers than between the one or more servers and the third BPHE.

In some embodiments, the first pump is configured to control a flow of the cooling tower fluid on the first fluid loop supplied from the cooling tower, and the cooling tower fluid flowing from the cooling tower to the third BPHE has a temperature lower than that flowing from the third BPHE to the cooling tower.

In some embodiments, the expansion valve is configured to control a flow of the refrigerant fluid on the DX loop. The refrigerant fluid has a temperature lower between the first BPHE and the expansion valve and between the expansion valve and the second BPHE than that between the second BPHE and the compressor and between the compressor and the first BPHE.

In some embodiments, the second BPHE is configured to heat-exchange the technical fluid that passed through the one or more servers and the third BPHE with the refrigerant fluid supplied from the expansion valve to the second BPHE. The technical fluid that passes through the third BPHE has a temperature higher than the target technical temperature.

In some embodiments, the compressor is configured to pressurize the refrigerant fluid that is heat-exchanged with the technical fluid at the second BPHE to be higher than an outside ambient temperature and to supply to the first BPHE.

In some embodiments, the first BPHE is configured to heat-exchange the refrigerant fluid, which is pressurized by the compressor, with the cooling tower fluid supplied from the cooling tower to the first BPHE.

In some embodiments, the cooling system further comprises a controller and a sensor, each of which communicates with at least one of the first fluid loop, the DX loop, or the second fluid loop.

In some embodiments, the controller is configured to control the DX loop to be selectively activated and deactivated based on sensing data obtained by the sensor.

In some embodiments, the sensing data comprises at least one of: a fluid flow rate on each of the first fluid loop, the DX loop, and the second fluid loop; a fluid temperature of each of the first fluid loop, the DX loop, and the second fluid loop; a temperature of each of one or more servers; or first and second pump conditions.

In some embodiments, the sensing data detected by the sensor is outside a threshold, the controller turns off at least one of the first pump of the first fluid loop, the compressor of the DX loop, or the second pump of the second water loop.

In some embodiments, the cooling system further comprises a coolant distribution unit (CDU) externally connected with the one or more servers that are disposed in a server cabinet. The CDU is configured to receive the technical fluid from the second pump and to supply the technical fluid to one or more servers.

In some embodiments, the cooling tower is disposed on a rooftop of the building.

In some embodiments, the cooling tower is disposed on a side wall of the building.

In accordance with at least one embodiment of the present disclosure, a cooling system for cooling one or more heat-generating components within a building. The system comprises at least one cooling tower positioned outside the building, a first fluid loop, a direct expansion (DX) loop, a second fluid loop, at least one sensor, and a controller. The first fluid loop in fluid communication with the cooling tower. The first fluid loop extends from the cooling tower outside the building to inside the building; the first fluid loop includes a first pump configured to circulate a cooling tower fluid. The direct expansion (DX) loop is in thermal communication with the cooling tower fluid of the first fluid loop. The DX loop is configured to circulate a refrigerant fluid and comprises an expansion valve and a compressor, and the DX loop is positioned within the building. The second fluid loop in thermal communication with the DX loop, the first fluid loop, and the one or more heat-generating components. The second fluid loop comprises a second pump configured to circulate a technical fluid, and the second fluid loop is positioned within the building. The sensor configured to generate sensing data based on at least one of the cooling tower fluid of the first fluid loop, the refrigerant fluid of the DX loop, and the technical fluid of the second fluid loop. The controller in electrical communication with the first pump, the second pump, the compressor, and the at least one sensor. The controller configured to adjust the operation of at least one of the first pump, the second pump, or the compressor based on the sensing data

In some embodiments, when the sensing data detected by the sensor is outside a threshold, the controller turns off at least one of the first pump of the first fluid loop, the compressor of the DX loop, or the second pump of the second water loop.

In some embodiments, the cooling system further comprises a first heat exchanger, a second heat exchanger, and a third heat exchanger. The first heat exchanger facilitating heat transfer between the refrigerant fluid of the DX loop and the cooling tower fluid of the first fluid loop. The second heat exchanger facilitates heat transfer between the refrigerant fluid of the DX loop and the technical fluid of the second fluid loop. The third heat exchanger facilitates heat transfer between the cooling tower fluid of the first loop and the technical fluid of the second fluid loop.

In accordance with at least one embodiment of the present disclosure, a cooling system for cooling one or more heat-generating components positioned within a building. The cooling system comprises a cooling tower positioned outside the building, a first fluid loop, a second fluid loop, a direct expansion fluid loop, a first heat exchanger, and a second heat exchanger. The first fluid loop is in fluid communication with the cooling tower outside the building. The first fluid loop comprises a first pump configured to circulate a cooling tower fluid through the first loop and the cooling tower. The second fluid loop is in fluid communication with one or more heat-generating components. The second fluid loop comprises a second pump configured to circulate a technical fluid through the second fluid and the heat-generating components. The direct expansion fluid loop is in thermal communication with the first fluid loop and the second fluid loop. The direct expansion loop comprises a refrigerant fluid, a compressor configured to circulate the refrigerant fluid through the direct expansion loop. The first heat exchanger receives and transfers heat from the refrigerant fluid to the cooling tower fluid. The cooling tower receives the technical fluid from the cooling tower fluid. The cooling tower rejects heat from the cooling tower fluid to the surrounding environment of the building

In some embodiments, the cooling system further comprises a third heat exchanger configured to receive the technical fluid and the cooling tower fluid and configured to transfer heat from the technical fluid to the cooling tower fluid

Other aspects and advantages of the invention will become apparent from the following detailed description, taken in conjunction with the accompanying drawings, illustrating by way of example the principles of the invention.

### BRIEF DESCRIPTION OF THE DRAWINGS

The disclosure will be readily understood by the following detailed description in conjunction with the accompanying drawings, wherein like reference numerals designate like elements:

FIG. 1 shows a schematic view of a standard air cooling system according to a related art;

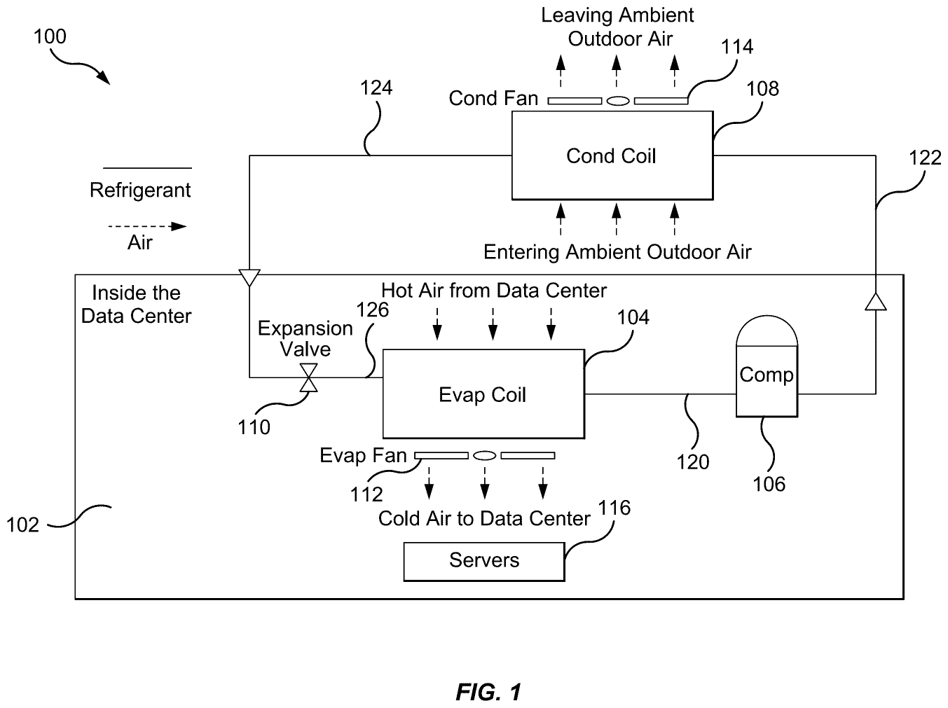

FIG. 2 shows a schematic view of a standard direct-to-chip liquid cooling system according to a related art;

FIG. 3A shows a schematic view of a direct-to-chip liquid cooling system according to embodiments of the present disclosure; and

FIG. 3B shows a side view of the direct-to-chip liquid cooling system.

### DETAILED DESCRIPTION

The figures described above and the written description of specific structures and functions below are not presented to limit the scope of what Applicant has invented or the scope of the appended claims. Rather, the Figures and written description are provided to teach any person skilled in the art to make and use the inventions for which patent protection is sought. Those skilled in the art will appreciate that not all features of a commercial embodiment of the inventions are described or shown for the sake of clarity and understanding. Persons of skill in this art will also appreciate that the development of an actual commercial embodiment incorporating aspects of the present inventions will require numerous implementation-specific decisions to achieve the developer's goal for the commercial embodiment. Such implementation-specific decisions may include and likely are not limited to, compliance with system-related, business-related, government-related, and other constraints, which may vary by specific implementation, location, and from time to time. While a developer's efforts might be complex and time-consuming in an absolute sense, such efforts would be, nevertheless, a routine undertaking for those of skill in this art having the benefit of this disclosure. It must be understood that the inventions disclosed and taught herein are susceptible to numerous and various modifications and alternative forms.

The use of a singular term, such as, but not limited to, “a,” is not intended as limiting of the number of items. The use of relational terms, such as, but not limited to, “top,” “bottom,” “left,” “right,” “upper,” “lower,” “down,” “up,” “side,” and the like are used in the written description for clarity in specific reference to the Figures and are not intended to limit the scope of the inventions or the appended claims. The terms “including” and “such as” are for illustrative purposes but not limited thereto. The terms “couple,” “coupled,” “coupling,” “coupler,” and like terms are used broadly herein and can include any method or device for securing, binding, bonding, fastening, attaching, joining, inserting therein, forming thereon or therein, communicating, or otherwise associating, for example, mechanically, magnetically, electrically, chemically, operably, directly or indirectly with intermediate elements, one or more pieces of members together and can further include without limitation integrally forming one functional member with another in a unity fashion. The coupling can occur in any direction, including rotationally. Further, all parts and components of the disclosure that are capable of being physically embodied inherently include imaginary and real characteristics regardless of whether such characteristics are expressly described herein, including but not limited to characteristics such as axes, ends, inner and outer surfaces, interior spaces, tops, bottoms, sides, boundaries, dimensions (e.g., height, length, width, thickness), mass, weight, volume, and density, among others.

The proposed systems implement some similarities to typical direct-to-chip liquid cooling designs; however, condensing coils, which supply only one unit, are replaced with cooling towers. Cooling towers have the capability to supply a larger quantity of units without increasing the amount of roof space required. Further, cooling towers produce colder water, as they are not limited by the ambient dry bulb temperature, but rather the ambient wet bulb temperature. This allows for free cooling to be utilized for longer periods throughout the year when compared to standard condenser coils.

This unit is unique since there are currently no cooling solutions that utilize a direct expansion (DX) cycle and cooling towers for the application of direct-to-chip liquid cooling. Other solutions lack one or more of the crucial aspects of this unit. Traditional direct-to-chip liquid cooling units are reliant on condenser fans to provide enough cooling, which is becoming an issue due to the increasing density of data centers and the amount of real estate needed to operate. Chiller systems are expensive and difficult to maintain and present a barrier of entry to liquid cooling, especially for customers who already own a cooling tower.

The term “data center” generally refers to a physical location housing one or more “servers”. The term “server” generally refers to a computing device connected to a computing network and running software configured to receive requests from client computing components. Such servers may also include specialized computing components such as network routers, data acquisition equipment, movable disc drive arrays, and other components commonly associated with data centers.

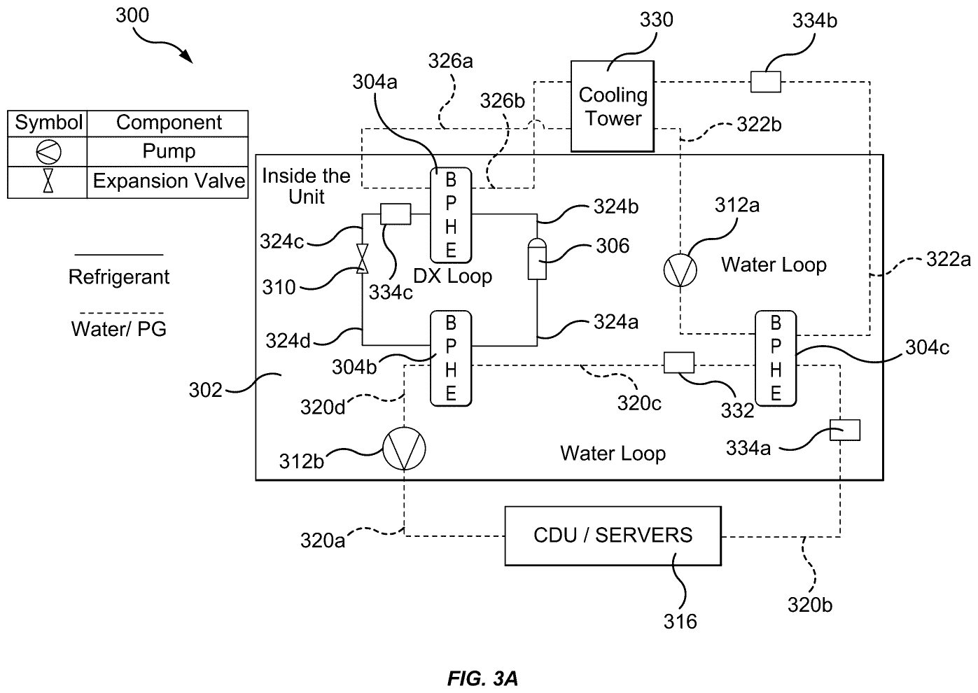

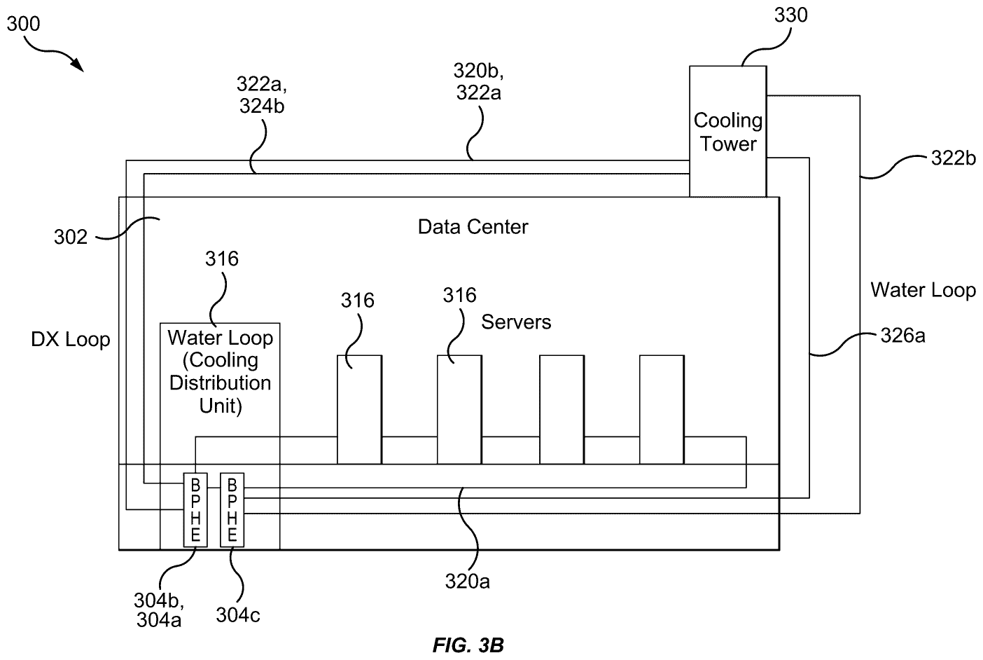

FIG. 3A shows a schematic view of a direct-to-chip liquid cooling system according to embodiments of the present disclosure. FIG. 3B shows a side view of the direct-to-chip liquid cooling system.

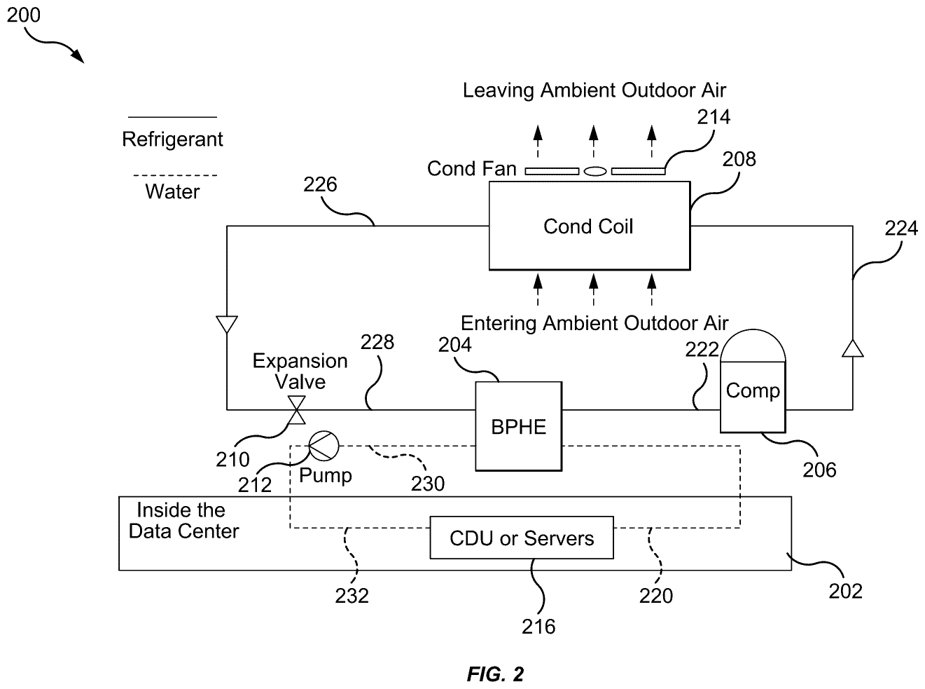

A direct-to-chip liquid cooling system 300 according to embodiments for a data center 302 may include similar components to the typical direct-to-chip liquid cooling system 200 described above with reference to FIG. 2, such as a brazed plate heat exchanger (BPHE), a pump, an expansion valve, and a compressor. For instance, the system 300 may include one or more BPHEs 304a-304c, a compressor 306, an expansion valve 310, and one or more pumps 312a, 312b. The system 300 may further include a cooling tower 330 outside the data center 302 as a main cooled fluid source.

A cooling tower is a heat removal device that uses water to transfer process waste heat into the atmosphere. Common applications of a cooling tower include cooling the circulating water used in oil refineries, petrochemicals, and other chemical plants, thermal power stations, nuclear power stations, and HVAC systems for cooling buildings. For chiller systems that utilize a cooling tower, heat transfer from the cooling process generally involves two stages. The heat generated by an industrial or commercial process is first transferred to the circulating chiller fluid by the condenser unit before atmospheric heat rejection at the cooling tower. Thus, using chillers and cooling towers together requires two levels of heat exchange. On the other hand, chillers with evaporative condensers achieve similar results by a single heat rejection process which involves the evaporation of heated water from the external surface of the coolant tubing. In addition, condensers do not require as much maintenance, they are more cost-effective for smaller systems and for smaller buildings. Thus, condenser systems are commonly used in most of the HVAC applications for data centers.

However, the need to increase the cooling capacity in data centers requires correspondingly larger chiller systems, which take up more space not only within but also outside the data center. The current direct-to-chip liquid cooling system using a condenser similar to the system 200 would not be able to satisfy the cooling capacity as needed or will be needed. The cooling tower 330 can solve some of the drawbacks that a condenser cannot provide.

In some embodiments, the direct-to-chip liquid cooling system 300 according to embodiments may include two cooling loops-a DX loop and a first water loop. The DX loop is similar to a typical DX loop formed by the first BPHE 304a, the expansion valve 310, the second BPHE 304b, and the compressor 306. The first water loop is formed by the cooling tower 330, the water loop pump 312a and the third BPHE 304c. The second and third BPHEs 304b and 304c are further connected with a second water loop for a coolant distribution unit (CDU) or server(s) 316, which will be described later in this disclosure.

The cooling tower 330 can provide a cooling effect to the first water loop and the DX loop, which bring heated fluid from the CDU or server(s) 316, more specifically, heated electronic devices connected to the CDU or server(s) 316. For example, a cold technical fluid may be pumped by the second pump 312b to be supplied to the CDU or server(s) 316 via a fluid line 320a. Here, the technical fluid may include more viscous fluids than water like ethylene glycol and water (EGW), oils, 3M Fluorinert®, Polyalphaolefin (PAO), and 25% Propylene Glycol (PG25). Alternatively, the second pump 312b may be a part of the CDU, which includes a heat exchanger, and may supply the technical fluid to one or more chips or servers. In some embodiments, the CDU and servers may be in one housing or cabinet or may be separately located. For instance, there may be a cabinet where one or more servers are housed, and a CDU may be externally connected to the cabinet. In some embodiments, there may be a cabinet in which both CDU and one or more servers are housed. In addition, the number of CDU and servers may vary, e.g., there may be one CDU externally or internally connected to one or more servers or may be two or more CDUs. Further, although FIG. 3A shows one pump 312b in the second water loop, there may be more than one pump, for example, a third pump is located within the CDU or between the CDU/servers 316 and the third BPHE 304c.

The technical fluid passing through the CDU or server(s) 316 is then heated by hot electronic devices or data chips on the servers on a fluid line 320b. The fluid line 320b then passes through the third BPHE 304c at which the heated technical fluid can be cooled, i.e., heat exchanged by cool water flowing through the first water loop. The firstly cooled technical fluid can then be supplied to the second BPHE 304b via a fluid line 320c to be further or secondly heat exchanged at the second BPHE 304b. Due to the extremely high heat generated at the CDU or server(s) 316 due to heated chips, the third BPHE 304c may not be able to cool the technical fluid enough to circulate back to the CDU or server(s) 316.

It is known that, as the operating temperature of electronic components increases, the components' life expectancy shortens. Additionally, operation at high temperatures can cause power fluctuations and failures that lead to various errors within the computing and electronic systems. If the heat dissipation is not consistently managed, heat will inevitably harm the structural and data integrity of the computing and electronic system. In addition, a lower air temperature in a data center allows each server component to dissipate a higher power and thus allows each server to dissipate more power and operate at a higher level of hardware performance. Therefore, the use of an auxiliary heat exchanger, e.g., a second BPHE 304b, can provide additional cooling of the technical fluid to provide sufficient cooling to the server. The secondarily cooled technical fluid can then flow through the pump 312b via a fluid line 320d to repeat the cooling process.

Returning back to the first water loop and the DX loop configurations, the cooling tower 330 provides cool water to the pump 312a via a fluid line 322b to be supplied to the BPHE 304c. This cool water helps to cool the heated technical fluid flowing through the BPHE 304c via the fluid line 320b as the typical heat exchanging technique. The water not heated at the BPHE 304c on the first water loop then flows back to the cooling tower via a fluid line 322a to be cooled.

The cooling tower 330 further supplies the cool water to the BPHE 304a via a fluid line 326a, which then exchanges the heat with the refrigerant flowing through the BPHE 304a. The heated water then flows back to the cooling tower 330 via a fluid line 326b to be cooled thereat.

Although the figures only show one pump in the DX loop, it is not limited thereto. There may be a pump between the cooling tower 330 and the BPHE 304a on the fluid line 326a and/or the fluid line 326b. Similarly, there may be additional pump(s) on the first water loop, for example, on the fluid line 322a, and additional pump(s) on the second water loop to facilitate the flow of fluid on each loop.

The cooling tower 330 described throughout the disclosure can be a typical cooling tower configured to circulate water therein and to be installed outside a building, e.g., data center. The shape and size are not limited to one specific configuration but different cooling tower shapes and sizes can be adapted to the system 300 according to embodiments. Further, two or more cooling towers may be used, or one cooling tower having one or more components . . . .

In some embodiments, the system 300 according to embodiments may further include one or more pump controllers (not shown), one or more various sensors, and a controller, which can communicate with each other. For instance, based on sensing data obtained from various sensors, the one or more pump controllers or the controller may control the pumps 312a and 312b, power supply, etc., and the controller may further control one or more of the elements of the system 300. The sensing data may include, but is not limited to, a fluid contamination (particle) sensor, a temperature sensor, a flow rate sensor, a voltage sensor, a speedometer, etc.

Additionally or optionally, the second water loop may include a temperature sensor 332 on the fluid line 320c between the second and third BPHEs 304b and 304c. When the temperature measured by the temperature sensor 332 is less than a target temperature, the DX loop may be disconnected from the second water loop or the DX loop may be deactivated.

In some embodiments, if a fault is detected in the DX loop, the water loop is controlled, e.g., the pump 312a may be controlled to increase the flow rate of the cooling water to ensure that the heat exchange at the BPHE 304c can provide enough cooling. On the other hand, if a fault is detected in the first water loop, the DX loop may be controlled to provide colder refrigerant than the normal operating cooling temperature. Thus, based on the detected temperature on the fluid line 320c, the DX loop may be selectively activated and deactivated. When there is a fault detected in the second water loop, the DX loop, the first water loop, and the second water loop may be all deactivated.

In some embodiments, there may be one controller communicating with the system 300 or one or more controllers 334a-c respectively communicating with the DX loop, the first water loop, and the second water loop. In further embodiments, there may be one or more additional water loops communicating between the cooling tower 330 and the second water loop, and/or one or more additional DX loops communicating between the cooling tower 330 and the second water loop.

FIG. 3B is a side view of the direct-to-chip liquid cooling system 300 of FIG. 3A. The cooling tower 330 may be installed on a rooftop of the data center building 302. As described above, the number of the cooling tower 330 may vary based on the need for cooling capacity, reconfiguration requirements, etc. In addition, although FIG. 3B shows only two BPHEs, there may be more than 2, e.g., 3 BPHEs as described above, or more. Detailed description of the elements of the direct-to-chip liquid cooling system 300 can be referred to above with reference to FIG. 3A and thus omitted herein.

The configuration of the direct-to-chip liquid cooling system 300 as shown can be achieved by simply replacing a condenser unit used in a typical direct-to-chip liquid cooling system (e.g., the system 200) and reconfiguring fluid lines to provide two cooling loops-DX loop and first water loop. This reconfigured system can provide higher cooling capacity desirable and necessary in the current or future data center, without requiring more space on the top of the building (i.e., rooftop). The system of the present disclosure can provide a simple and efficient way to adopt high-density direct-to-chip liquid cooling with minimal existing infrastructure. The ability to retrofit existing facilities and setups brings several benefits, from environmental to cost perspectives.

In this application, including the definitions below, the term “module” or the term “controller” may be replaced with the term “circuit.” The term “module” refers to or includes: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Peri, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

None of the elements recited in the claims are intended to be a means-plus-function element within the meaning of 35 U.S.C. § 112(f) unless an element is expressly recited using the phrase “means for,” or in the case of a method claim using the phrases “operation for” or “step for.”

Although the terms first, second, third, etc. may be used herein to describe various elements, pumps, condenser fans, compressors, circuits, components and/or modules, these items should not be limited by these terms. These terms may be only used to distinguish one item from another item. Terms such as “first,” “second,” and other numerical terms when used herein do not imply a sequence or order unless clearly indicated by the context. Thus, a first item discussed herein could be termed a second item without departing from the teachings of the example implementations.

Process flowcharts discussed herein illustrate the operation of possible implementations of systems, methods, and computer program products according to various embodiments of the present invention. In this regard, each block in the flowchart may represent a module, segment, or portion of code, which comprises one or more executable instructions for implementing the specified logical function(s). It should also be noted that, in some alternative implementations, the functions noted in the blocks might occur out of the order depicted in the figures. For example, blocks shown in succession may be executed substantially concurrently. It will also be noted that each block of flowchart illustration can be implemented by special-purpose hardware-based systems that perform the specified functions or acts, or combinations of special purpose hardware and computer instructions.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not intended to be exhaustive or to limit the embodiments to the precise forms disclosed. It will be apparent to one of ordinary skill in the art that many modifications and variations are possible in view of the above teachings.

What is claimed is:

1. A cooling system for cooling one or more heat-generating components within a building, the cooling system comprising:
at least one cooling tower disposed outside the building;
a first fluid loop directly communicating with the cooling tower, wherein the first fluid loop is configured to circulate a cooling tower fluid and includes a first pump;
a direct expansion (DX) loop indirectly communicating with the cooling tower, wherein the DX loop is configured to circulate a refrigerant fluid and comprises an expansion valve and a compressor; and
a second fluid loop indirectly communicating with the DX loop, the first fluid loop, and one or more heat-generating components, wherein the second fluid loop is configured to circulate a technical fluid and comprises a second pump,
wherein the DX loop communicates with the cooling tower via a first brazed plate heat exchanger (BPHE) and communicates with the second fluid loop via a second BPHE,
wherein the first fluid loop communicates with the second fluid loop via a third BPHE,
wherein the DX loop and the second fluid loop are disposed inside the building, and
wherein the one or more heat-generating components is one or more servers.

2. The system of claim 1, wherein the second pump is configured to control a flow of the technical fluid in the second fluid loop, and
wherein the technical fluid in the second fluid loop has a temperature lower between the second pump and the one or more servers than that between the one or more servers and the third BPHE.

3. The system of claim 1, wherein the first pump is configured to control a flow of the cooling tower fluid on the first fluid loop supplied from the cooling tower, and
wherein the cooling tower fluid flowing from the cooling tower to the third BPHE has a temperature lower than that flowing from the third BPHE to the cooling tower.

4. The system of claim 3, wherein the third BPHE is configured to heat-exchange the technical fluid passed through the one or more servers with the cooling tower fluid supplied from the first pump to the third BPHE.

5. The system of claim 1, wherein the expansion valve is configured to control a flow of the refrigerant fluid on the DX loop, and
wherein the refrigerant fluid has a temperature lower between the first BPHE and the expansion valve and between the expansion valve and the second BPHE than that between the second BPHE and the compressor and between the compressor and the first BPHE.

6. The system of claim 5, wherein the second BPHE is configured to heat-exchange the technical fluid that passed through the one or more servers and the third BPHE with the refrigerant fluid supplied from the expansion valve to the second BPHE,
wherein the technical fluid that passed through the third BPHE has a temperature higher than the target technical temperature.

7. The system of claim 6, wherein the compressor is configured to pressurize the refrigerant fluid that is heat-exchanged with the technical fluid at the second BPHE to be higher than an outside ambient temperature and to supply to the first BPHE.

8. The system of claim 7, wherein the first BPHE is configured to heat-exchange the refrigerant fluid, which is pressurized by the compressor, with the cooling tower fluid supplied from the cooling tower to the first BPHE.

9. The system of claim 1, further comprising a controller and a sensor, each of which communicates with at least one of the first fluid loop, the DX loop, or the second fluid loop.

10. The system of claim 9, wherein the controller is configured to control the DX loop to be selectively activated and deactivated based on sensing data obtained by the sensor.

11. The system of claim 10, wherein the sensing data comprises at least one of: a fluid flow rate on each of the first fluid loop, the DX loop, and the second fluid loop; a fluid temperature of each of the first fluid loop, the DX loop, and the second fluid loop; a temperature of each of one or more servers; or first and second pump conditions.

12. The system of claim 10, wherein, when the sensing data detected by the sensor is outside a threshold, the controller turns off at least one of the first pump of the first fluid loop, the compressor of the DX loop, or the second pump of the second water loop.

13. The system of claim 1, further comprising a coolant distribution unit (CDU) externally connected with the one or more servers that are disposed in a server cabinet,
wherein the CDU is configured to receive the technical fluid from the second pump and to supply the technical fluid to one or more servers.

14. The system of claim 1, wherein the cooling tower is disposed on a rooftop of the building.

15. The system of claim 1, wherein the cooling tower is disposed on a side wall of the building.

16. A cooling system for cooling one or more heat-generating components positioned within a building, the system comprising:
at least one cooling tower positioned outside the building;
a first fluid loop in fluid communication with the cooling tower, the first fluid loop extends from the cooling tower outside the building to inside the building; the first fluid loop includes a first pump configured to circulate a cooling tower fluid;
a direct expansion (DX) loop in thermal communication with the cooling tower fluid of the first fluid loop, the DX loop is configured to circulate a refrigerant fluid and comprises an expansion valve and a compressor, and the DX loop is positioned within the building;
a second fluid loop in thermal communication with the DX loop, the first fluid loop, and the one or more heat-generating components, the second fluid loop comprises a second pump configured to circulate a technical fluid, and the second fluid loop is positioned within the building;
at least one sensor configured to generate sensing data based on at least one of the cooling tower fluid of the first fluid loop, the refrigerant fluid of the DX loop, and the technical fluid of the second fluid loop; and
a controller in electrical communication with the first pump, the second pump, the compressor, and the at least one sensor, the controller configured to adjust the operation of at least one of the first pump, the second pump, or the compressor based on the sensing data.

17. The system of claim 16, wherein, when the sensing data detected by the sensor is outside a threshold, the controller turns off at least one of the first pump of the first fluid loop, the compressor of the DX loop, or the second pump of the second water loop.

18. The cooling system of claim 16, further comprising:
a first heat exchanger facilitating heat transfer between the refrigerant fluid of the DX loop and the cooling tower fluid of the first fluid loop;
a second heat exchanger facilitating heat transfer between the refrigerant fluid of the DX loop and the technical fluid of the second fluid loop; and
a third heat exchanger facilitating heat transfer between the cooling tower fluid of the first loop and the technical fluid of the second fluid loop.

19. A cooling system for one or more heat-generating components positioned within a building, the cooling system comprising:
a cooling tower positioned outside the building;
a first fluid loop in fluid communication with the cooling tower outside the building, the first fluid loop comprising
a first pump configured to circulate a cooling tower fluid through the first fluid loop and the cooling tower;
a second fluid loop in fluid communication with one or more heat-generating components, the second fluid loop comprising
a second pump configured to circulate a technical fluid through the second fluid loop and the heat-generating components;
a direct expansion fluid loop in thermal communication with the first fluid loop and the second fluid loop, the direct expansion fluid loop comprising
a refrigerant fluid,
a compressor configured to circulate the refrigerant fluid through the direct expansion fluid loop;
a first heat exchanger configured to receive and transfer heat from the refrigerant fluid to the cooling tower fluid,
a second heat exchanger configured to receive the technical fluid from the cooling tower fluid, and
wherein the cooling tower rejects heat from the cooling tower fluid to the surrounding environment of the building.

20. The cooling system of claim 19, further comprising a third heat exchanger configured to receive the technical fluid and the cooling tower fluid, the third heat exchanger configured to transfer heat from the technical fluid to the cooling tower fluid.
